(19) United States
(12) Patent Application Publication
(10) Pub. No.: US 2023/0420329 A1
(43) Pub. Date: Dec. 28, 2023

(54) TOP SIDE COOLED SEMICONDUCTOR PACKAGES

(71) Applicant: Wolfspeed, Inc., Durham, NC (US)

(72) Inventors: Adil Salman, Morrisville, NC (US); Ajay Sekar Chandrasekaran, Santa Clara, CA (US); Kuldeep Saxena, Sewickley, PA (US)

(21) Appl. No.: 17/849,316

(22) Filed: Jun. 24, 2022

(51) Int. Cl. H01L 23/367; H01L 23/373; H01L 23/00

(52) U.S. Cl. CPC H01L 23/3675; H01L 23/3677; H01L 23/3735; H01L 24/48; H01L 2224/48091; H01L 2224/73265

(57) ABSTRACT

Top-side cooled semiconductor packages are disclosed. A top-side cooled semiconductor package may be a leaded or a leadless semiconductor package. A top-side cooled semiconductor package can include built-in electrical isolation for a semiconductor die within a housing of the semiconductor package. A top-side cooled semiconductor package may include one or more arrangements of creepage extension structures. A creepage extension structure may be arranged as part of a top side of a housing, of part of at least one peripheral side of the housing, as part of a bottom side of the housing, or combinations thereof.

### FIELD OF THE DISCLOSURE

The present disclosure relates to semiconductor packages and, more particularly, to semiconductor packages with increased thermal conductivity capabilities.

### BACKGROUND

Semiconductor devices such as transistors and diodes are ubiquitous in modern electronic devices. Wide bandgap semiconductor material systems such as gallium arsenide (GaAs), gallium nitride (GaN), and silicon carbide (SiC) are being increasingly utilized in semiconductor devices to push the boundaries of device performance in areas such as switching speed, power handling capability, and thermal conductivity. Exemplary power semiconductor dies include metal-oxide-semiconductor field-effect transistors (MOSFETs), insulated gate bipolar transistors (IGBTs), Schottky barrier diodes, PiN diodes, thyristors, and high electron mobility transistors (HEMTs).

Packaging technology can play a large role in the performance of power semiconductor dies. For example, the packaging of a power semiconductor die may limit the ability of the semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

### SUMMARY

The present disclosure relates to top-side cooled semiconductor packages that house a semiconductor die. A top-side cooled semiconductor package may be a leadless top-side cooled semiconductor package or a leaded top-side cooled semiconductor package. A top-side cooled semiconductor package may include built-in electrical isolation for the semiconductor die within a housing of the top-side cooled semiconductor package. For example, the housing of a top-side cooled semiconductor package can include a power substrate, such as a direct bond copper (DBC) substrate. To promote increased current and voltage capabilities, a top-side cooled semiconductor package may include one or more arrangements of creepage extension structures. Creepage extension structures may be included anywhere in the housing of the top-side cooled semiconductor package. For example, a creepage extension structure may be part of a top side of the housing and/or a bottom side of the housing. Creepage extension structures may also be arranged as part of the top side and along or part of one or more peripheral sides of a top-side cooled semiconductor package.

In certain embodiments, the semiconductor die includes a transistor, such as a MOSFET. In some embodiments, the transistor is a SiC-based transistor. In other embodiments, the semiconductor die includes a diode. One example of a diode is a Schottky diode.

In one aspect, a top-side cooled semiconductor package includes a housing and a first contact within the housing at a top side of the housing. The first contact is included in a thermal transfer path for the top-side cooled semiconductor package. A semiconductor die is within the housing below the first contact. The semiconductor die includes a contact pad at a first side of the semiconductor die. A second contact is within the housing at or near a bottom side of the housing. An electrical connector operably connects the second contact to the contact pad of the semiconductor die. A creepage extension structure that includes one or more trenches extends into the top side of the housing.

In another aspect, a system includes a top-side cooled semiconductor package, a heat sink operably connected to the top side of the housing, and a circuit board operably connected to the bottom side of the housing. The top-side cooled semiconductor package includes a housing having a top side and a bottom side. The top-side cooled semiconductor package includes a housing and a first contact within the housing at a top side of the housing. The first contact is included in a thermal transfer path for the top-side cooled semiconductor package. A semiconductor die is within the housing below the first contact. The semiconductor die includes a contact pad at a first side of the semiconductor die. A second contact is within the housing at or near a bottom side of the housing. An electrical connector operably connects the second contact to the contact pad of the semiconductor die.

In another aspect, a top-side cooled semiconductor package includes a housing and a first contact within the housing at a top side of the housing. A semiconductor die is within the housing below the first contact. The semiconductor die includes a contact pad at a first side of the semiconductor die. A power substrate is within the housing between the first contact and a second side of the semiconductor die. The first contact and the power substrate are included in a thermal transfer path of the top-side cooled semiconductor package. A second contact is within the housing at a bottom side of the housing. An electrical connector operably connects the second contact to the contact pad of the semiconductor die.

In yet another aspect, a top-side cooled semiconductor package includes a housing and a first contact within the housing at a top side of the housing. The first contact is included in a thermal transfer path of the top-side cooled semiconductor package. A semiconductor die is within the housing below the first contact. The semiconductor die includes a first contact pad at a first side of the semiconductor die that is operably connected to the first contact and a second contact pad at a second side of the semiconductor die. A second contact is within the housing at or near a bottom side of the housing. An electrical connector operably connects the second contact to the second contact pad of the semiconductor die.

In certain embodiments, a creepage extension structure extends into one or more sides of the housing of the top-side cooled semiconductor package. The creepage extension structure includes one or more trenches that may be formed in a top side of the housing, a bottom side of the housing, at least one peripheral side of the housing, or combinations thereof. Each trench in the creepage extension structure can have any shape, such as a rectangular shape, a “V” shape, or a “U” shape. Additionally, each trench may extend to any depth in a side of the housing. For example, a creepage extension structure may extend into a top side of the housing. The creepage extension structure includes three (3) trenches that all have the same shape and the same depth. In another example, two of the three trenches in the creepage extension structure have a first shape and a first depth while the third trench has a different second shape and/or a different second depth. Additionally, each trench can have any width along the side of the housing.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a side view of an example first system according to embodiments of the disclosure;

FIG. 2 illustrates a cross-sectional view of an example of the first semiconductor package shown in FIG. 1 according to embodiments of the present disclosure;

FIG. 3 illustrates a bottom view of the first semiconductor package shown in FIG. 1 and FIG. 2 with the housing represented as transparent for illustrative purposes according to embodiments of the present disclosure;

FIG. 4 illustrates a top view of the first semiconductor package shown in FIG. 1 and FIG. 2 with the housing represented as transparent for illustrative purposes according to embodiments of the present disclosure;

FIG. 5 illustrates a side view of an example second system according to embodiments of the disclosure;

FIG. 6 illustrates a cross-sectional view of a first example of the second semiconductor package shown in FIG. 5 according to embodiments of the present disclosure;

FIG. 7 illustrates a bottom view of the first example of the second semiconductor package shown in FIG. 6 with the housing represented as transparent for illustrative purposes according to embodiments of the present disclosure;

FIG. 8 illustrates a cross-sectional view of a second example of the second semiconductor package shown in FIG. 5 according to embodiments of the present disclosure;

FIG. 9 illustrates a bottom view of the second example of the second semiconductor package shown in FIG. 8 with the housing represented as transparent for illustrative purposes according to embodiments of the present disclosure; and

FIG. 10 illustrates a side view of a housing for a semiconductor package showing example creepage extension structures according to embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Discrete semiconductor packages have been developed that include a semiconductor die, such as a MOSFET or a Schottky diode. Such semiconductor packages with MOSFETs may be employed in a variety of applications to enable higher switching frequencies along with reduced associated losses, higher blocking voltages, and improved avalanche capabilities. Exemplary applications include high performance industrial power supplies, server/telecom power, electric vehicle charging systems, energy storage systems, uninterruptible power supplies, high-voltage DC/DC converters, and battery management systems. Discrete semiconductor packages with Schottky diodes may be employed in many of the same high-performance power applications described above for MOSFETs, sometimes in systems that also include discrete power packages of MOSFETs. As discussed above, the packaging technology for semiconductor devices plays an important role in defining the performance thereof. In particular, the packaging for semiconductor devices is often a limiting factor for the semiconductor die therein to dissipate heat, conduct current, and even switch at particular speeds.

The present disclosure relates to top-side cooled semiconductor packages that house a semiconductor die. In certain aspects, top-side cooled semiconductor packages may include top-side cooled power semiconductor packages that include power semiconductor dies. As described earlier, a top-side cooled semiconductor package may be a leadless top-side cooled semiconductor package or a leaded top-side cooled semiconductor package. The housing of a top-side cooled semiconductor package may include built-in electrical isolation for the semiconductor die. For example, a top-side cooled semiconductor package can include a power substrate, such as a direct bond copper (DBC) substrate. To promote increased current and voltage capabilities, a top-side cooled semiconductor package may include one or more arrangements of creepage extension structures. Creepage extension structures may be included anywhere in the housing as part of the top-side cooled semiconductor package.

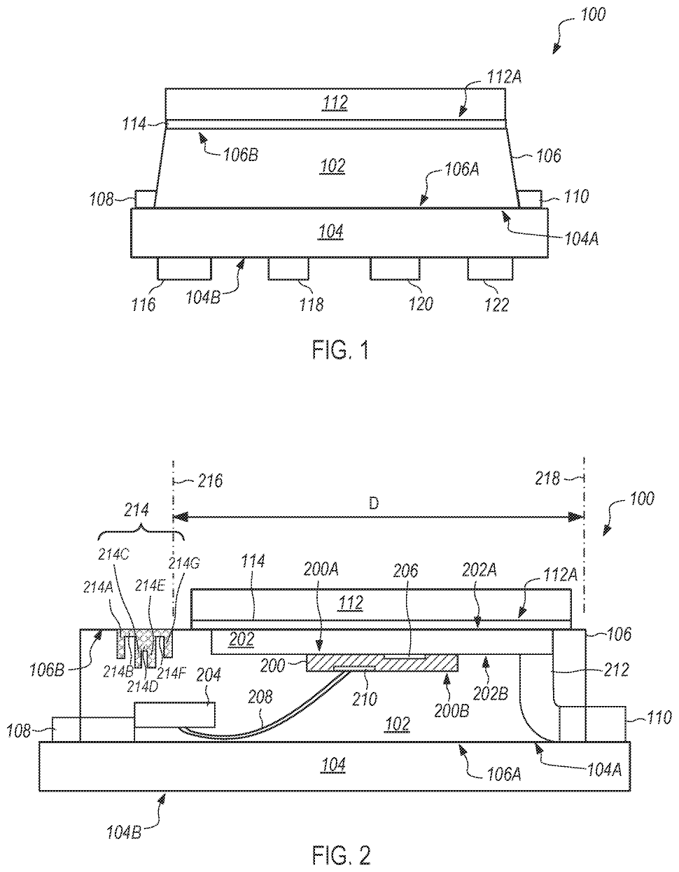

FIG. 1 illustrates a side view of an example first system 100 according to embodiments of the disclosure. The first system 100 includes an exterior of a first semiconductor package 102 mounted on a circuit board 104. The first semiconductor package 102 may be arranged to house and provide external electrical connections to a semiconductor die that is located within a housing 106. In certain embodiments, the semiconductor die is a power semiconductor die that can include components such as transistors, diodes, or thyristors. Example transistors include, but are not limited to, MOSFETs or IGBTs. Example diodes include, but are not limited to, Schottky barrier diodes, PiN diodes, or high electron mobility transistors (HEMTs). In some embodiments, the component(s) in the semiconductor die is a silicon carbide (SiC) based component, such as a SiC based MOSFET.

The housing 106 may be formed by a molding process such that the housing 106 is provided around the semiconductor die (shown in FIG. 2), one or more contacts (shown in FIG. 2), portions of one or more first pins (collectively first pin 108), and portions of one or more second pins (collectively second pin 110). The housing 106 may also be provided around one or more wire bonds, one or more conductive clips, and/or one or more conductive segments (not shown in FIG. 1). The material of the housing 106 can electrically isolate the components within the housing 106 from each other. Example materials for the housing 106 include an epoxy material or an epoxy mold compound (EMC).

The first semiconductor package 102 is a leadless semiconductor package. The first semiconductor package 102 may be arranged as a surface mount technology (SMT) package such that a bottom side 106A of the housing 106 is mounted on a first side 104A of the circuit board 104. Any suitable circuit board 104 may be used. In non-limiting nonexclusive examples, the circuit board 104 is a printed circuit board (PCB) or a flexible printed circuit board. External electrical connections for the first semiconductor package 102, and the included semiconductor die, may be provided by a structure that includes the first pin 108 and/or a structure that includes the second pin 110. In certain embodiments, the structure that includes the first pin 108 and/or the second pin 110 includes a wire bond, a conductive segment, a conductive clip, or other type of electrical connector.

A heat sink 112 is positioned over the first semiconductor package 102. In particular, a first side 112A of the heat sink 112 is disposed over a top side 106B of the housing 106. The heat sink 112 is included in a heat transfer path of the first semiconductor package 102. Heat generated by the semiconductor die within the housing 106 is directed to the top side 106B of the housing 106, where the heat sink 112 dissipates the heat. In certain embodiments, an interface material 114 is positioned between the first side 112A of the heat sink 112 and the top side 106B of the housing 106. In certain embodiments, the interface material 114 is a thermal interface adhesive or a thermal interface paste that can increase the thermal conductivity between the heat sink 112 and the housing 106. The interface material 114 also provides electrical isolation between the heat sink 112 and the semiconductor die within the housing 106.

In some embodiments, one or more components may be operably attached to a second side 104B of the circuit board 104. Although FIG. 1 depicts four (4) components 116, 118, 120, 122 operably attached to the second side 104B of the circuit board 104, any number of components may be operably attached to the second side 104B of the circuit board 104. Any suitable component, such as an electrical component (e.g., passive component) or an electronic component (e.g., active component), may be operably attached to the second side 104B of the circuit board 104. Non-limiting nonexclusive examples of components are resistors, capacitors, inductors, sensors, diodes, transistors, or integrated circuits.

FIG. 2 illustrates a cross-sectional view of an example of the first semiconductor package 102 shown in FIG. 1 according to embodiments of the present disclosure. The first semiconductor package 102 includes a semiconductor die 200, a first contact 202, and a second contact 204. The first contact 202 and the second contact 204 may be made of any suitable conductive material, such as metal. A first side 202A of the first contact 202 is positioned at the top side 106B of the housing 106. The first side 202A of the first contact 202 can be exposed in that the first side 202A is not covered by the top side 106B of the housing 106. In certain embodiments, the first side 202A of the first contact 202 is co-planar with the top side 106B of the housing 106.

A first side 200A of the semiconductor die 200 is attached to a second side 202B of the first contact 202. A first contact pad 206 at the first side 202A of the semiconductor die 200 is operably connected (e.g., electrically connected) to the second side 202B of the first contact 202.

The second contact 204 is positioned at or near the bottom side 106A of the housing 106. A first electrical connector 208 operably connects (e.g., electrically connects) the second contact 204 to a second contact pad 210 at a second side 200B of the semiconductor die 200. In the illustrated embodiment, the first electrical connector 208 is a wire bond. The first electrical connector 208 may be implemented differently in other embodiments. For example, the first electrical connector 208 may be a conductive segment, a conductive clip, or another type of electrical connector.

The first pin 108 and the second pin 110 are positioned at or near the bottom side 106A of the housing 106. The first pin 108 and the second pin 110 may be made of any suitable conductive material, such as metal. The second contact 204 is operably connected to the first pin 108. As shown in FIG. 2, the second contact 204 physically and electrically contacts the first pin 108. Accordingly, an electrical signal (e.g., a voltage or a current) may be transmitted between the semiconductor die 200 and the first pin 108 via the second contact 204, the first electrical connector 208, and the second contact pad 210.

A second electrical connector 212 operably connects the second pin 110 to the first contact 202. An electrical signal (e.g., a voltage or a current) can be transmitted between the semiconductor die 200 and the second pin 110 via the second electrical connector 212, the first contact 202, and the first contact pad 206. In FIG. 2, the second electrical connector 212 is a conductive segment, but other embodiments are not limited to this configuration. The second electrical connector 212 may be a wire bond, a conductive clip, or another type of electrical connector in other embodiments.

The first side 104A of the circuit board 104 is arranged over the bottom side 106A of the housing 106 and can be operably connected to the first semiconductor package 102. Although not shown in FIG. 2, one or more components may be operably connected to the second side 104B of the circuit board 104.

The first semiconductor package 102 may further include one or more creepage extension structures (collectively referred to as a creepage extension structure 214). When the first semiconductor package 102 includes the creepage extension structure 214, the creepage extension structure 214 can be formed as part of the top side 106B of the housing 106 in a location that is between the first pin 108 and the first contact 202. In this manner, the creepage extension structure 214 may be configured to improve voltage isolation between the first pin 108 and the first contact 202. Voltage isolation is an increasing challenge in semiconductor packages, particularly as package sizes continue to shrink. The creepage extension structure 214 effectively increases a surface distance, or a creepage distance, along the housing 106 between the first pin 108 and the first contact 202 without having to position the first pin 108 and the first contact 202 farther apart, thereby allowing a smaller overall footprint of the first semiconductor package 102. In certain embodiments, the creepage distance may be provided in a range from five (5) millimeters (mm) to twenty (20) mm, or in a range of five (5) mm to fifteen (15) mm, or in a range of five (5) mm to ten (10) mm, or in a range from ten (10) mm to twenty (20) mm, or in a range from twelve (12) mm to twenty (20) mm, or in a range from twelve (12) mm to fifteen (15) mm, or in a range from three (3) mm to ten (10) mm depending on the power handling capability of the first semiconductor package 102.

As illustrated, the creepage extension structure 214 may be formed as a number of slots or trenches 214A, 214B, 214C, 214D, 214E, 214F, 214G that extend into the housing 106 from the top side 106B. The trenches 214A-214G may have the same dimensions or at least one of the trenches 214A-214G can have at least one dimension that differs from the other trenches 214A-214G. For example, as shown in FIG. 2, the trenches 214C and 214E are formed to a first depth (e.g., a deepest depth), the trenches 214A and 214G are formed to a different second depth (e.g., a first intermediate depth), the trench 214D is formed to a different third depth (e.g., a second intermediate depth), and the trenches 214B and 214F are formed to a different fourth depth (e.g., a shallowest depth). Additionally or alternatively, a width (e.g., along the top side 106B of the housing) of the trenches 214A-214G may be the same or the width of at least one of the trenches 214A-214G can differ from the widths of the other trenches 214A-214G.

The creepage extension structure 214 may also be referred to as having a number of ribs or protrusions that are formed by portions of the housing 106 that are between the trenches 214A-214G. The creepage extension structure 214 may be formed concurrently with molding of the housing 106 about the first pin 108 and the first contact 202. In certain embodiments, the creepage extension structure 214 is arranged only as part of the top side 106B and along a shortest path of the housing 106 that is between the first pin 108 and the first contact 202. In other embodiments, the creepage extension structure 214 may be arranged as part of the top side 106B of the housing 106, as part of at least one peripheral side of the housing 106, as part of the bottom side 106A of the housing 106, or combinations thereof.

The interface material 114 is disposed over the top side 106B of the housing 106 and over the first side 202A of the first contact 202. The first side 112A of the heat sink 112 is arranged over the interface material 114. As such, the first side 202A of the first contact 202 is in thermal contact with the first side 112A of the heat sink 112. The first contact 202 and the heat sink 112 are included in the heat transfer path of the first semiconductor package 102. Heat generated by the semiconductor die 200 is directed to the top side 106B of the housing 106 by the first contact 202. The first contact 202 transfers the heat to the heat sink 112 (via the interface material 114) and the heat sink 112 dissipates the heat. Since the first contact 202 is configured to propagate an electrical signal, the interface material 114 provides electrical isolation between the first contact 202 and the heat sink 112 to prevent the electrical signal from propagating to the heat sink 112.

The heat sink 112 can have any dimension (e.g., width and length) with respect to the top side 106B of the housing 106 and/or with respect to the first contact 202. When the housing 106 includes the creepage extension structure 214 at the top side 106B of the housing 106, the heat sink 112 may have any width that is within dotted line 216 and dotted line 218 (e.g., a distance D). The dotted line 216 corresponds to the right-side edge of the trench 214G. The dotted line 218 corresponds to the right-side edge of the housing 106. In one non-limiting nonexclusive example, a width of the heat sink 112 is equal to a width of the first contact 202. In another non-limiting nonexclusive example, a width of the heat sink 112 is greater than the width of the first contact 202 but less than the distance D.

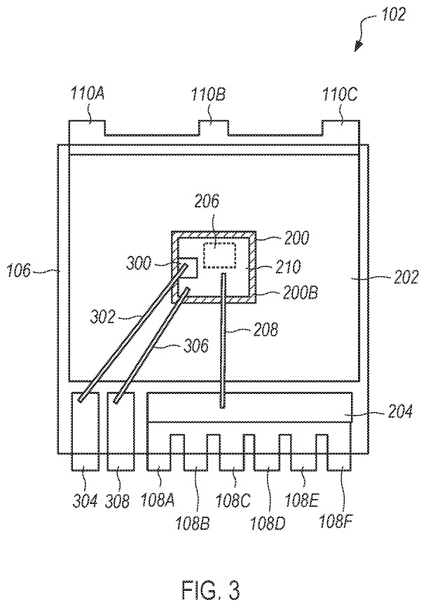

FIG. 3 illustrates a bottom view of the first semiconductor package 102 shown in FIG. 1 with the housing 106 represented as transparent for illustrative purposes according to embodiments of the present disclosure. As described earlier, the first semiconductor package 102 includes the first contact 202, the second contact 204, and the semiconductor die 200. The first electrical connector 208 operably connects the second contact 204 to the second contact pad 210 at the second side 200B of the semiconductor die 200. The illustrated second contact pad 210 is shown as a single contact pad. However, in other embodiments, the second contact pad 210 may be configured as two or more contact pads to reduce or eliminate issues associated with current crowding. One or more jumper connectors can be used to operably connect the two or more contact pads to each other. Additionally or alternatively, embodiments can include one or more first electrical connectors 208.

The semiconductor die 200 also includes the first contact pad 206. The first contact pad 206 is shown in dashed lines because the first contact pad 206 is at the first side of the semiconductor die 200 (e.g., the first side 200A in FIG. 2), so the first contact pad 206 is not visible in the bottom view of the first semiconductor package 102 shown in FIG. 3. The first contact pad 206 is operably connected (e.g., physically in contact with and electrically connected) to the first contact 202.

First pins 108A, 108B, 108C, 108D, 108E, 108F are configured to provide an electrical signal to the second contact 204 and/or to receive an electrical signal from the second contact 204. Second pins 110A, 110B, 110C are configured to provide an electrical signal to the first contact 202 and/or to receive an electrical signal from the first contact 202. Although FIG. 3 depicts six (6) first pins 108A, 108B, 108C, 108D, 108E, 108F and three (3) second pins 110A, 110B, 110C, other embodiments can include one or more first pins 108 and one or more second pins 110.

In one non-limiting nonexclusive example, the semiconductor die 200 includes a diode, such as a Schottky diode. As such, the first contact pad 206 is operably connected to a first terminal of the diode (e.g., an anode terminal), and the second contact pad 210 is operably connected to a second terminal of the diode (e.g., a cathode terminal). The first contact pad 206 may also be referred to as a first terminal contact pad and the second contact pad 210 as a second terminal contact pad. The first pins 108A-108F are operably connected to the second contact pad 210 via the second contact 204 and the first electrical connector 208. The second pins 110A-110C are operably connected to the first contact pad 206 via the second electrical connector 212 (see FIG. 2) and the first contact 202.

In another non-limiting nonexclusive example, the semiconductor die 200 includes a transistor (e.g., a MOSFET). As such, the first contact pad 206 (may also be referred to as a first terminal contact pad or a drain contact pad) is operably connected to a first terminal of the transistor (e.g., the drain), and the second contact pad 210 (may also be referred to as a second terminal contact pad or a source contact pad) is operably connected to a second terminal of the transistor (e.g., a source terminal). Again, the first pins 108A-108F are operably connected to the second contact pad 210 via the second contact 204 and the first electrical connector 208. The second pins 110A-110C are operably connected to the first contact pad 206 via the second electrical connector 212 (see FIG. 2) and the first contact 202.

When the component of the semiconductor die 200 can use an addition contact pad (e.g., as with a transistor), the semiconductor die 200 further includes a third contact pad 300 that is operably connected to a third terminal of the component (e.g., a gate of the transistor). A third electrical connector 302 operably connects the third contact pad 300 to a third pin 304. The third contact pad 300 may also be referred to as a gate contact pad or a third terminal contact pad, and the third pin 304 as a gate pin. An electrical signal can be transmitted to the third contact pad 300 and/or receive from the third contact pad 300. For example, an electrical signal to be applied to the gate of the transistor is input into the first semiconductor package 102 at the third pin 304. The third electrical connector 302 transmits the electrical signal to the third contact pad 300 and the electrical signal is applied to the third terminal (e.g., the gate of the transistor).

In certain embodiments, a kelvin connection to the source of the transistor is used to improve a switching speed and/or a switching efficiency of the transistor. FIG. 3 depicts a kelvin connection to the second contact pad 210 (e.g., the source contact pad). A fourth electrical connector 306 operably connects a fourth pin 308 (may also be referred to as a kelvin pin) to the second contact pad 210. The third electrical connector 302 and the fourth electrical connector 306 are shown as wire bonds in FIG. 3. However, the third electrical connector 302 and the fourth electrical connector 306 can each be any suitable type of an electrical connector, such as a wire bond, a conductive segment, or a conductive clip.

The components in the first semiconductor package 102 can vary depending on the component(s) in the semiconductor die 200. For example, the third contact pad 300, the third electrical connector 302, and the third pin 304 may be included in certain embodiments (e.g., when the semiconductor die 200 includes a transistor). Alternatively, the third contact pad 300, the third electrical connector 302, and the third pin 304 can be omitted in other embodiments. Similarly, the kelvin connection (the fourth pin 308 and the fourth electrical connector 306) may be included in certain embodiments and omitted in other embodiments.

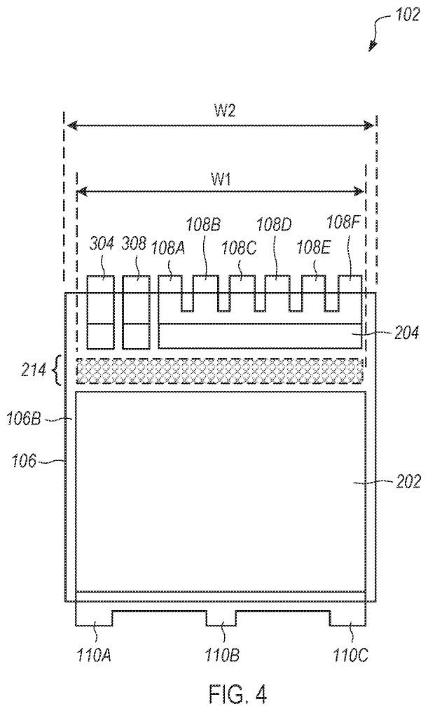

FIG. 4 illustrates a top view of the first semiconductor package 102 of FIG. 1 with the housing 106 represented as transparent for illustrative purposes according to embodiments of the present disclosure. The example first semiconductor package 102 includes the first contact 202, the second contact 204, the first pins 108A-108F, the second pins 110A-110C, the third pin 304, and the fourth pin 308. The first contact 202 is shown as a relatively large conductive contact, which is also known as a “tab”, when compared to the area of the second contact 204. However, other embodiments can include the first contact 202 and the second contact 204 that each have any given area.

The creepage extension structure 214 is formed in the top side 106B of the housing 106. The creepage extension structure 214 has a first width W1. Thus, the trenches 214A-214G (FIG. 2) in the creepage extension structure 214 all have the same width W1. As discussed previously, at least one trench 214A-214G can have a width that differs from the width of the other trenches 214A-214G. In the example embodiment, the width W1 is less than the width W2 of the housing 106.

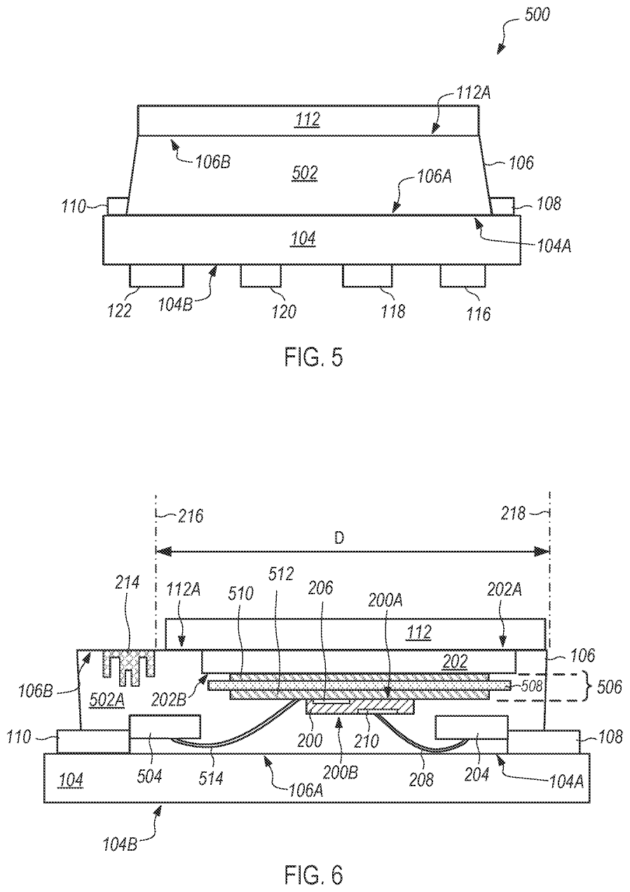

FIG. 5 illustrates a side view of an example second system 500 according to embodiments of the disclosure. The second system 500 is similar to the example first system 100 shown in FIG. 1 but with the omission of the interface material 114. As will be described in more detail in conjunction with FIG. 6, a second semiconductor package 502 includes built-in electrical isolation for the semiconductor die within the second semiconductor package 502. Consequently, the interface material 114 is not included in the example second system 500.

In addition to the second semiconductor package 502, the example second system 500 includes the heat sink 112 arranged over the top side 106B of the housing 106 and the circuit board 104 positioned over the bottom side 106A of the housing 106. In FIG. 5, the heat sink 112 is in direct contact with the top side 106B of the housing 106 and with the first side 202A of the first contact 202 as a result of the built-in electrical isolation.

The housing 106 may be formed by a molding process such that the housing 106 is provided around the semiconductor die (not shown in FIG. 5), multiple contacts (not shown in FIG. 5), a power substrate (not shown in FIG. 5), a portion of the first pin 108, and a portion of the second pin 110. The housing 106 may also be provided around one or more wire bonds, one or more conductive clips, and/or one or more conductive segments (not shown in FIG. 5). As described earlier, the material of the housing 106 can electrically isolate the components within the housing 106 from each other.

Like the first semiconductor package 102 (FIG. 1), the second semiconductor package 502 may be arranged as an SMT package such that the bottom side 106A of the housing 106 is mounted on the first side 104A of the circuit board 104. External electrical connections for the second semiconductor package 502, and the included semiconductor die, may be provided by a structure that includes the first pin 108 and/or a structure that includes the second pin 110. In certain embodiments, the structure that includes the first pin 108 and/or the second pin 110 includes a wire bond, a conductive segment, a conductive clip, or other suitable electrical connector.

In certain embodiments, one or more components may be operably attached to the second side 104B of the circuit board 104. Although FIG. 5 depicts four (4) components 116, 118, 120, 122 operably attached to the second side 104B of the circuit board 104, any number of components may be operably attached to the second side 104B of the circuit board 104. Non-limiting nonexclusive examples of components are resistors, capacitors, inductors, sensors, diodes, transistors, or integrated circuits.

FIG. 6 illustrates a cross-sectional view of a first example of the second semiconductor package 502A shown in FIG. 5 according to embodiments of the present disclosure. The second semiconductor package 502A is a leadless semiconductor package. The second semiconductor package 502A includes the semiconductor die 200, the first contact 202, the second contact 204, and a third contact 504. The first side 202A of the first contact 202 can be exposed in that the first side 202A is not covered by the top side 106B of the housing 106. In certain embodiments, the first side 202A of the first contact 202 is co-planar with the top side 106B of the housing 106. The first side 202A of the first contact 202 is positioned at the top side 106B of the housing 106. The second contact 204 and the third contact 504 are at or near the bottom side 106A of the housing 106. The first contact 202, the second contact 204, and the third contact 504 may be made of any suitable conductive material, such as metal.

The first side 200A of the semiconductor die 200 is attached to a power substrate 506. The power substrate 506 is a thermally conductive substrate and an electrically insulating substrate. The power substrate 506 includes an insulating layer 508 sandwiched between a first conductive layer 510 and a second conductive layer 512. In a non-limiting non-exclusive example, the insulating layer 508 is a ceramic layer and the first conductive layer 510 and the second conductive layer 512 are copper layers. As such, the power substrate 506 is a DBC substrate. The power substrate 506 may be implemented differently in other embodiments.

The first conductive layer 510 of the power substrate 506 is attached to the second side 202B of the first contact 202. The power substrate 506, the first contact 202, and the heat sink 112 are included in a thermal transfer path of the second semiconductor package 502A. Heat generated by the semiconductor die 200 is directed to the top side 106B of the housing 106 by the power substrate 506 and the first contact 202. Since the first side 202A of the first contact 202 is in thermal contact with the first side 112A of the heat sink 112, the first contact 202 transfers the heat to the heat sink 112 and the heat sink 112 dissipates the heat.

The first contact pad 206 at the first side 200A of the semiconductor die 200 is operably connected (e.g., electrically connected) to the second conductive layer 512 of the power substrate 506. A second electrical connector 514 operably connects the third contact 504 to the second conductive layer 512 of the power substrate 506. The third contact 504 is operably connected to the second pin 110. As shown in FIG. 5, the third contact 504 electrically contacts the second pin 110. Accordingly, an electrical signal (e.g., a voltage or a current) may be transmitted between the semiconductor die 200 and the second pin 110 via the third contact 504, the second electrical connector 514, the second conductive layer 512, and the first contact pad 206.

The first electrical connector 208 operably connects the second contact 204 to the second contact pad 210 at the at the second side 200B of the semiconductor die 200. In the illustrated embodiment, the first electrical connector 208 and the second electrical connector 514 are wire bonds. The first electrical connector 208 and/or the second electrical connector 514 may be implemented differently in other embodiments. For example, the first electrical connector 208 and/or the second electrical connector 514 may each be a conductive segment, a conductive clip, or another type of electrical connector.

The first pin 108 and the second pin 110 are positioned at the bottom side 106A of the housing 106. The first pin 108 and the second pin 110 may be made of any suitable conductive material, such as metal.

The first side 104A of the circuit board 104 is arranged over the bottom side 106A of the housing 106 and can be operably connected to the second semiconductor package 502A. Although not shown in FIG. 6, one or more components may be operably connected to the second side 104B of the circuit board 104.

The second semiconductor package 502A may also include the creepage extension structure 214. When the second semiconductor package 502A includes the creepage extension structure 214, the creepage extension structure 214 is formed at least as part of the top side 106B of the housing 106 in a location that is between the second pin 110 and the first contact 202. The creepage extension structure 214 effectively increases the creepage distance along the housing 106 between the second pin 110 and the first contact 202 without having to position the second pin 110 and the first contact 202 farther apart. In certain embodiments, the creepage distance may be provided in a range from five (5) millimeters (mm) to twenty (20) mm, or in a range of five (5) mm to fifteen (15) mm, or in a range of five (5) mm to ten (10) mm, or in a range from ten (10) mm to twenty (20) mm, or in a range from twelve (12) mm to twenty (20) mm, or in a range from twelve (12) mm to fifteen (15) mm, or in a range from three (3) mm to ten (10) mm depending on the power handling capability of the second semiconductor package 502A.

The creepage extension structure 214 may be formed concurrently with the molding of the housing 106 about the second pin 110 and the first contact 202. In certain embodiments, the creepage extension structure 214 is arranged only as part of the top side 106B of the housing 106 that is between the second pin 110 and the first contact 202. In other embodiments, the creepage extension structure 214 may be arranged as part of the top side 106B of the housing 106, as part of at least one peripheral side of the housing 106, as part of the bottom side 106A of the housing 106, or combinations thereof.

The heat sink 112 can have any dimension (e.g., width and length) with respect to the top side 106B of the housing 106 and/or with respect to the first contact 202. When the housing 106 includes the creepage extension structure 214 at the top side 106B of the housing 106, the heat sink 112 may have any width that is within the dotted line 216 and the dotted line 218 (e.g., a distance D). The dotted line 216 corresponds to the right-side edge of the creepage extension structure 214. The dotted line 218 corresponds to the right-side edge of the housing 106. In one non-limiting nonexclusive example, a width of the heat sink 112 is equal to a width of the first contact 202. In another non-limiting nonexclusive example, a width of the heat sink 112 is greater than the width of the first contact 202 but less than the distance D.

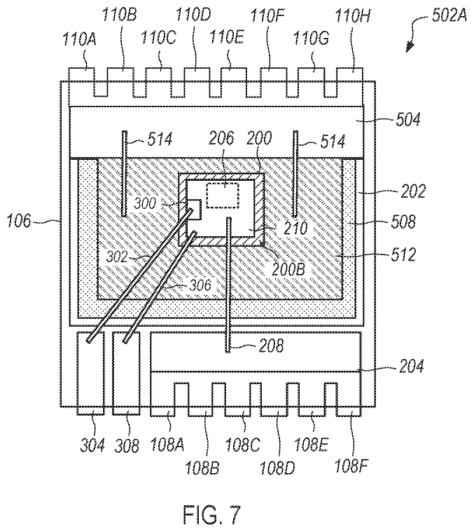

FIG. 7 illustrates a bottom view of the first example of the second semiconductor package 502A shown in FIG. 6 with the housing 106 represented as transparent for illustrative purposes according to embodiments of the present disclosure. As described earlier, the second semiconductor package 502A includes the first contact 202, the second contact 204, the third contact 504, and the semiconductor die 200. The first electrical connector 208 operably connects the second contact 204 to the second contact pad 210 at the second side 200B of the semiconductor die 200. The illustrated second contact pad 210 is shown as a single contact pad. However, as described previously, the second contact pad 210 may be configured as two or more contact pads with jumper connectors operably connecting the two or more contact pads to each other. Additionally or alternatively, embodiments can include one or more first electrical connectors 208.

The semiconductor die 200 also includes the first contact pad 206. The first contact pad 206 is shown in dashed lines because the first contact pad 206 is at the first side of the semiconductor die 200 (e.g., the first side 200A in FIG. 6), so the first contact pad 206 is not visible in the bottom view of the second semiconductor package 502A of FIG. 7. The first contact pad 206 is operably connected to (e.g., in physical contact with and electrically connected to) the second conductive layer 512 of the power substrate 506. The second electrical connectors 514 operably connect the third contact 504 to the second conductive layer 512 of the power substrate 506. Although FIG. 7 depicts two second electrical connectors 514, other embodiments can include one or more second electrical connectors 514

The insulating layer 508 of the power substrate is also shown in FIG. 7. As described earlier, the first conductive layer 510 is positioned between the insulating layer 508 and the first contact 202. However, the first conductive layer 510 is not visible in the bottom view of the second semiconductor package 502A of FIG. 7.

First pins 108A, 108B, 108C, 108D, 108E, 108F are configured to provide an electrical signal to the second contact 204 and/or to receive an electrical signal from the second contact 204. Second pins 110A, 110B, 110C, 110D, 110E, 110F, 110G, 110H are configured to provide an electrical signal to the third contact 504 and/or to receive an electrical signal from the third contact 504. Although FIG. 7 depicts six (6) first pins 108A-108F, and eight (8) second pins 110A-110H, other embodiments can include one or more first pins 108 and one or more second pins 110.

In one non-limiting nonexclusive example, the semiconductor die 200 includes a diode, such as a Schottky diode. As such, the first contact pad 206 is operably connected to a first terminal of the diode (e.g., an anode terminal), and the second contact pad 210 is operably connected to a second terminal of the diode (e.g., a cathode terminal). The first pins 108A-108F are operably connected to the second contact pad 210 via the second contact 204 and the first electrical connector 208. The second pins 110A-110H are operably connected to the first contact pad 206 via the third contact 504, the second electrical connectors 514, and the second conductive layer 512.

In another non-limiting nonexclusive example, the semiconductor die 200 includes a transistor (e.g., a MOSFET). As such, the first contact pad 206 is operably connected to a first terminal of the transistor (e.g., the drain), and the second contact pad 210 is operably connected to a second terminal of the transistor (e.g., a source terminal). Again, the first pins 108A-108F are operably connected to the second contact pad 210 via the second contact 204 and the first electrical connector 208. The second pins 110A-110H are operably connected to the first contact pad 206 via the third contact 504, the second electrical connectors 514, and the second conductive layer 512.

When the component of the semiconductor die 200 can use an addition contact pad (e.g., as with a transistor), the semiconductor die 200 further includes the third contact pad 300 that is operably connected to a third terminal of the component (e.g., a gate of the transistor). The third electrical connector 302 operably connects the third contact pad 300 to the third pin 304 (e.g., the gate pin). An electrical signal can be transmitted to the third contact pad and/or receive from the third contact pad. For example, an electrical signal to be applied to the gate of the transistor is input into the second semiconductor package 502A at the third pin 304. The third electrical connector 302 transmits the electrical signal to the third contact pad 300 and the electrical signal is applied to the third terminal (e.g., the gate of the transistor).

In certain embodiments, the kelvin connection to the source of the transistor is included in the second semiconductor package 502A. The fourth electrical connector 306 operably connects the fourth pin 308 (e.g., the kelvin pin) to the second contact pad 210. The third electrical connector 302 and the fourth electrical connector 306 can each be any suitable type of an electrical connector, such as a wire bond, a conductive segment, or a conductive clip.

The components in the second semiconductor package 502A can vary depending on the component(s) in the semiconductor die 200. For example, the third contact pad 300, the third electrical connector 302, and the third pin 304 may be included in certain embodiments (e.g., when the semiconductor die 200 includes a transistor). Alternatively, the third contact pad 300, the third electrical connector 302, and the third pin 304 can be omitted in other embodiments. Similarly, the kelvin connection (the fourth pin 308 and the fourth electrical connector 306) may be included in certain embodiments and omitted in other embodiments.

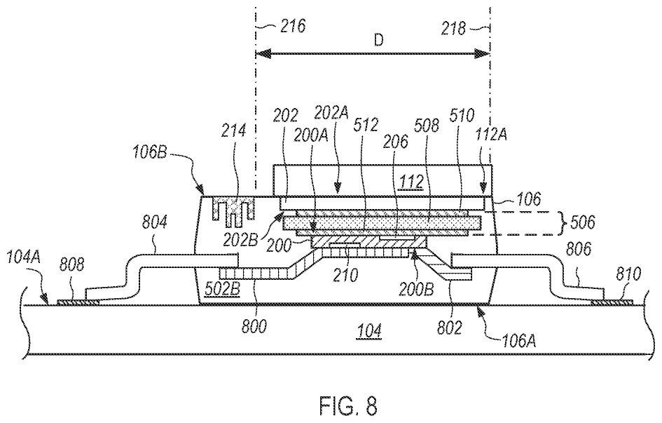

FIG. 8 illustrates a cross-sectional view of a second example of the second semiconductor package 502B shown in FIG. 5 according to embodiments of the present disclosure. The second semiconductor package 502B is similar to the second semiconductor package 502A shown in FIG. 6 except that the third contact 504 and the second electrical connector 514 are replaced with a first conductive clip 800, and the second contact 204 and the first electrical connector 208 are replaced with a second conductive clip 802. Additionally, the second pin 110 is replaced with one or more first leads (collectively first lead 804) and the first pin 108 is replaced with one or more second leads (collectively second lead 806). Accordingly, the second semiconductor package 502B is a leaded semiconductor package.

As described earlier, the first contact 202 is positioned at the top side 106B of the housing 106 and the first side 202A of the first contact 202 may be co-planar with the top side 106B of the housing 106. The first conductive clip 800, the second conductive clip 802, the first lead 804, and the second lead 806 are positioned at or near the bottom side 106A of the housing 106. The first conductive clip 800, the second conductive clip 802, the first lead 804, and the second lead 806 may each be made of any suitable conductive material, such as metal.

The first conductive layer 510 of the power substrate 506 is attached to the second side 202B of the first contact 202. Similar to the second semiconductor package 502A of FIG. 6, the power substrate 506, the first contact 202, and the heat sink 112 are included in a thermal transfer path of the second semiconductor package 502A. Heat generated by the semiconductor die 200 is directed to the top side 106B of the housing 106 by the power substrate 506 and the first contact 202. Since the first side 202A of the first contact 202 is in thermal contact with the first side 112A of the heat sink 112, the first contact 202 transfers the heat to the heat sink 112 for dissipation.

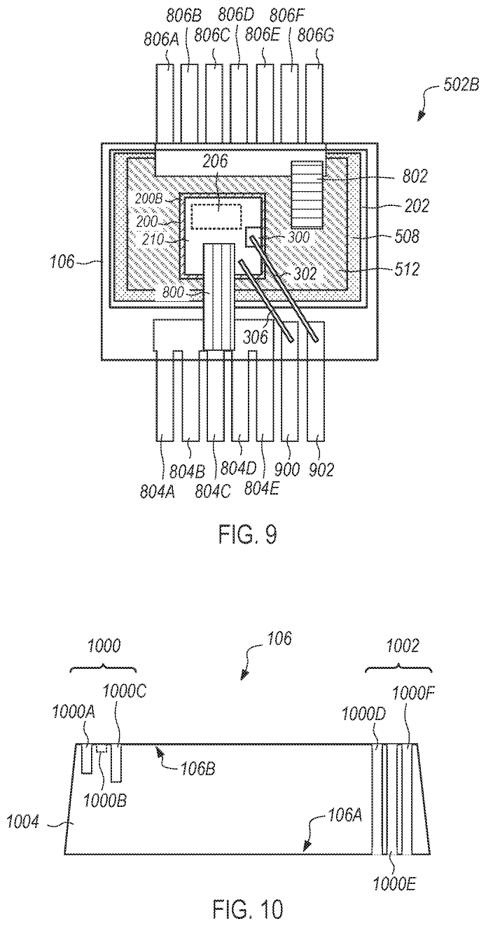

The first contact pad 206 at the first side 200A of the semiconductor die 200 is operably connected (e.g., physically in contact with and electrically connected) to the second conductive layer 512 of the power substrate 506. The second conductive clip 802 operably connects the second lead 806 to the second conductive layer 512 of the power substrate 506 (shown in FIG. 9). Accordingly, an electrical signal (e.g., a voltage or a current) may be transmitted between the semiconductor die 200 and the second lead 806 via the second conductive clip 802 and the first contact pad 206.

The first conductive clip 800 is operably connected between the first lead 804 and the second contact pad 210 at the second side 200B of the semiconductor die 200. Accordingly, an electrical signal (e.g., a voltage or a current) may be transmitted between the semiconductor die 200 and the first lead 804 via the second conductive clip 802 and the second contact pad 210. The first lead 804 and/or the second lead 806 may be implemented differently in other embodiments. For example, the first lead 804 and/or the second lead 806 may be a conductive segment, a wire bond, or another type of electrical connector.

A third contact pad 808 and a fourth contact pad 810 are positioned at the first side 104A of the circuit board 104. The first lead 804 is operably connected to the third contact pad 808. The second lead 806 is operably connected to the fourth contact pad 810. The third contact pad 808 and the fourth contact pad 810 may be made of any suitable conductive material, such as metal.

The first side 104A of the circuit board 104 is arranged over the bottom side 106A of the housing 106 and can be operably connected to the second semiconductor package 502B. Although not shown in FIG. 8, one or more components may be operably connected to the second side 104B of the circuit board 104.

The second semiconductor package 502B may also include the creepage extension structure 214. When the second semiconductor package 502B includes the creepage extension structure 214, the creepage extension structure 214 is formed at least as part of the top side 106B of the housing 106 in a location that is between the first lead 804 and the first contact 202. The creepage extension structure 214 effectively increases the creepage distance along the housing 106 between the first lead 804 and the first contact 202 without having to position the first lead 804 and the first contact 202 farther apart. In certain embodiments, the creepage distance may be provided in a range from five (5) millimeters (mm) to twenty (20) mm, or in a range of five (5) mm to fifteen (15) mm, or in a range of five (5) mm to ten (10) mm, or in a range from ten (10) mm to twenty (20) mm, or in a range from twelve (12) mm to twenty (20) mm, or in a range from twelve (12) mm to fifteen (15) mm, or in a range from three (3) mm to ten (10) mm depending on the power handling capability of the second semiconductor package 502B.

The creepage extension structure 214 may be formed concurrently with the molding of the housing 106 about the first lead 804 and the first contact 202. In certain embodiments, the creepage extension structure 214 is arranged only as part of the top side 106B of the housing 106 that is between the first lead 804 and the first contact 202. In other embodiments, the creepage extension structure 214 may be arranged as part of the top side 106B, as part of at least one peripheral side of the housing 106, as part of the bottom side 106A of the housing 106, or combinations thereof.

The heat sink 112 can have any dimension (e.g., width and length) with respect to the top side 106B of the housing 106 and/or with respect to the first contact 202. When the housing 106 includes the creepage extension structure 214 at the top side 106B of the housing 106, the heat sink 112 may have any width that is within the dotted line 216 and the dotted line 218 (e.g., the distance D). The dotted line 216 corresponds to the right-side edge of the creepage extension structure 214. The dotted line 218 corresponds to the right-side edge of the housing 106. In one non-limiting nonexclusive example, a width of the heat sink 112 is equal to a width of the first contact 202. In another non-limiting nonexclusive example, a width of the heat sink 112 is greater than the width of the first contact 202 but less than the distance D.

FIG. 9 illustrates a bottom view of the second example of the second semiconductor package 502B shown in FIG. 8 with the housing 106 represented as transparent for illustrative purposes according to embodiments of the present disclosure. As described earlier, the second semiconductor package 502B includes the first contact 202, the semiconductor die 200, the first conductive clip 800, and the second conductive clip 802. The first conductive clip 800 operably connects the first leads 804A, 804B, 804C, 804D, 804E to the second contact pad 210 at the second side 200B of the semiconductor die 200. The illustrated second contact pad 210 is shown as a single contact pad. However, in other embodiments, the second contact pad 210 may be configured as two or more contact pads with jumper connectors operably connecting the two or more contact pads to each other.

The semiconductor die 200 also includes the first contact pad 206. The first contact pad 206 is shown in dashed lines because the first contact pad 206 is at the first side of the semiconductor die 200 (e.g., the first side 200A in FIG. 8), so the first contact pad 206 is not visible in the bottom view of the second semiconductor package 502B of FIG. 9. The first contact pad 206 is operably connected to (e.g., in physical contact with and electrically connected to) the second conductive layer 512 of the power substrate 506. The second conductive clip 802 operably connects the second leads 806A, 806B, 806C, 806D, 806E, 806F, 806G to the second conductive layer 512 of the power substrate 506.

The insulating layer 508 of the power substrate is also shown in FIG. 9. As described earlier, the first conductive layer 510 is positioned between the insulating layer 508 and the first contact 202. However, the first conductive layer 510 is not visible in the bottom view of the second semiconductor package 502B of FIG. 9.

First leads 804A-804E are configured to provide an electrical signal to the first conductive clip 800 and/or to receive an electrical signal from the first conductive clip 800. Second leads 806A-806G are configured to provide an electrical signal to the second conductive clip 802 and/or to receive an electrical signal from the second conductive clip 802. Although FIG. 9 depicts five (5) first leads 804A-804E and seven (7) second leads 806A-806G, other embodiments can include one or more first leads 804 and one or more second leads 806.

In one non-limiting nonexclusive example, the semiconductor die 200 includes a diode, such as a Schottky diode. As such, the first contact pad 206 is operably connected to a first terminal of the diode (e.g., an anode terminal), and the second contact pad 210 is operably connected to a second terminal of the diode (e.g., a cathode terminal). The first leads 804A-804E are operably connected to the second contact pad 210 via the first conductive clip 800. The second leads 806A-806G are operably connected to the first contact pad 206 via the second conductive clip 802 and the second conductive layer 512 of the power substrate.

In another non-limiting nonexclusive example, the semiconductor die 200 includes a transistor, such as a MOSFET. As such, the first contact pad 206 is operably connected to a first terminal of the transistor (e.g., the drain), and the second contact pad 210 is operably connected to a second terminal of the transistor (e.g., a source terminal). Again, the first leads 804A-804E are operably connected to the second contact pad 210 via the first conductive clip 800. The second leads 806A-806G are operably connected to the first contact pad 206 via the second conductive clip 802 and the second conductive layer 512 of the power substrate.

When the component of the semiconductor die 200 can use an addition contact pad (e.g., as with a transistor), the semiconductor die 200 further includes the third contact pad 300 that is operably connected to a third terminal of the component (e.g., the gate of the transistor). The third electrical connector 302 operably connects the third contact pad 300 to the third pin 304 (e.g., the gate pin). An electrical signal to be applied to the gate of the transistor is input into the second semiconductor package 502A at the third pin 304. The third electrical connector 302 transmits the electrical signal to the third contact pad 300 and the electrical signal is applied to the gate of the transistor.

In certain embodiments, the kelvin connection to the source of the transistor is included in the second semiconductor package 502B. The fourth electrical connector 306 operably connects the fourth pin 308 (e.g., the kelvin pin) to the second contact pad 210. The third electrical connector 302 and the fourth electrical connector 306 can be any suitable electrical connector, such as a wire bond, a conductive segment, a conductive clip, or any other type of an electrical connector.

Like the second semiconductor package 502A shown in FIG. 7, the components in the second semiconductor package 502B can vary depending on the component(s) in the semiconductor die 200. For example, the third contact pad 300, the third electrical connector 302, and the third pin 304 may be included in certain embodiments (e.g., when the semiconductor die 200 includes a transistor). Alternatively, the third contact pad 300, the third electrical connector 302, and the third pin 304 can be omitted in other embodiments. Similarly, the kelvin connection (the fourth pin 308 and the fourth electrical connector 306) may be included in certain embodiments and omitted in other embodiments.

FIG. 10 illustrates a side view of the housing 106 for a semiconductor package showing a first example creepage extension structure 1000 and a second example creepage extension structure 1002 according to embodiments of the present disclosure. The first example creepage extension structure 1000 includes trenches 1000A, 1000B, 1000C. The trenches 1000A, 1000C are formed in (and extend along) the top side 106B of the housing 106 and a portion of the peripheral side 1004 of the housing 106. Although not shown in FIG. 10, the trenches 1000A, 1000C may also extend along a part of another peripheral side of the housing 106. The trench 1000B is only formed in, and only extends along, the top side 106B of the housing 106. Accordingly, the trench 1000B is shown in dashed lines.

The second example creepage extension structure 1002 includes trenches 1000D, 1000E, 1000F. The trenches 1000D, 1000E, 1000F are formed in (and extend along) the top side 106B of the housing 106 and the entire length of the peripheral side 1004 of the housing 106. Although not shown in FIG. 10, the trenches 1000D, 1000E, 1000F may also extend along at least a part of another peripheral side of the housing 106.

In other embodiments, the housing 106 can include any number of trenches. The trenches may be rectangular in shape or can have any other type of shape (e.g., a “V” shape or a “U” shape). The dimensions (e.g., width and length) of the trenches can be the same or the dimensions of at least one trench may differ from the dimensions of the other trenches.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A top-side cooled semiconductor package comprising:
a housing;
a first contact within the housing at a top side of the housing, the first contact included in a thermal transfer path for the top-side cooled semiconductor package;
a semiconductor die within the housing below the first contact, the semiconductor die comprising a contact pad at a first side of the semiconductor die;
a second contact within the housing at a bottom side of the housing;
an electrical connector operably connecting the second contact to the contact pad of the semiconductor die; and
a creepage extension structure that extends into a side of the housing, the creepage extension structure comprising one or more trenches.

2. The top-side cooled semiconductor package of claim 1, wherein:
the contact pad is a first contact pad;
the semiconductor die further comprises a second contact pad at a second side of the semiconductor die; and
the first contact is operably connected to the second contact pad of the semiconductor die.

3. The top-side cooled semiconductor package of claim 2, wherein:
the semiconductor die includes a diode;
the first contact pad is a first terminal contact pad operably connected to a first terminal of the diode; and
the second contact pad is a second terminal contact pad operably connected to a second terminal of the diode.

4. The top-side cooled semiconductor package of claim 2, wherein:
the semiconductor die includes a transistor;
the first contact pad is a first terminal contact pad operably connected to a first terminal of the transistor;
the second contact pad is a second terminal contact pad operably connected to a second terminal of the transistor; and
the semiconductor die further comprises a third terminal contact pad at the first side of the semiconductor die, the third terminal contact pad operably connected to a third terminal of the transistor.

5. The top-side cooled semiconductor package of claim 1, further comprising a power substrate between the first contact and the semiconductor die.

6. The top-side cooled semiconductor package of claim 5, wherein the power substrate comprises an insulating layer between a top conductive layer and a bottom conductive layer.

7. The top-side cooled semiconductor package of claim 6, wherein the power substrate is a direct bond copper substrate.

8. The top-side cooled semiconductor package of claim 6, wherein:
the electrical connector is a first electrical connector;
the contact pad is a first contact pad;
the semiconductor die comprises a second contact pad at a second side of the semiconductor die, the second contact pad operably connected to the bottom conductive layer of the power substrate; and
the top-side cooled semiconductor package further comprises:
a third contact within the housing at the bottom side of the housing; and
a second electrical connector operably connecting the third contact to the bottom conductive layer of the power substrate.

9. The top-side cooled semiconductor package of claim 8, wherein:
the first electrical connector is one of a first wire bond, a first conductive segment, or a first conductive clip; and
the second electrical connector is one of a second wire bond or a second conductive segment, or a second conductive clip.

10. The top-side cooled semiconductor package of claim 8, wherein:
the semiconductor die comprises a metal-oxide-semiconductor field-effect transistor (MOSFET);
the first contact pad is a source contact pad operably connected to a source of the MOSFET;
the second contact pad is a drain contact pad operably connected to a drain of the MOSFET;
the semiconductor die further comprises a gate contact pad at the first side of the semiconductor die, the gate contact pad operably connected to a gate of the MOSFET; and
the top-side cooled semiconductor package further comprises a third electrical connector operably connecting the gate contact pad to a gate pin at the bottom side of the housing.

11. The top-side cooled semiconductor package of claim 10, further comprising a fourth electrical connector operably connecting a kelvin pin on the bottom side of the housing to the source contact pad of the semiconductor die.

12. The top-side cooled semiconductor package of claim 1, wherein:
the side of the housing is the top side of the housing; and
the creepage extension structure provides a creepage distance between a pin or a lead and the first contact that is in a range from twelve millimeters (mm) to twenty mm.

13. The top-side cooled semiconductor package of claim 12, wherein the creepage extension structure includes at least one trench that further extends into at least one peripheral side of the housing.

14. The top-side cooled semiconductor package of claim 1, wherein the creepage extension structure provides a creepage distance that is in a range from five millimeters (mm) to fifteen mm or in a range from three mm to ten mm.

15. The top-side cooled semiconductor package of claim 1, wherein the top-side cooled semiconductor package is a leadless top-side cooled semiconductor package.

16. A system, comprising:
a top-side cooled semiconductor package, the top-side cooled semiconductor package comprising a housing having a top side and a bottom side;
a heat sink operably connected to the top side of the housing; and
a circuit board operably connected to the bottom side of the housing,
wherein the top-side cooled semiconductor package comprises:
a first contact within the housing at the top side of the housing, the first contact and the heat sink included in a thermal transfer path for the top-side cooled semiconductor package;
a semiconductor die within the housing below the first contact, the semiconductor die comprising a contact pad at a first side of the semiconductor die;
a second contact within the housing at a bottom side of the housing;
an electrical connector operably connecting the second contact to the contact pad of the semiconductor die; and
a creepage extension structure that extends into at least one side of the housing, the creepage extension structure comprising one or more trenches.

17. The system of claim 16, wherein:
the top-side cooled semiconductor package is operably connected to a first side of the circuit board; and
the system further comprises an electronic component operably attached to a second side of the circuit board.

18. The system of claim 16, wherein:
the contact pad is a first contact pad;
the semiconductor die further comprising a second contact pad at a second side of the semiconductor die; and
the first contact is operably connected to the second contact pad of the semiconductor die.

19. (canceled)

20. (canceled)

21. The system of claim 16, wherein the top-side cooled semiconductor package further comprises a power substrate positioned between the first contact and the semiconductor die.

22. (canceled)

23. The system of claim 21, wherein:
the electrical connector is a first electrical connector;
the contact pad is a first contact pad;
the semiconductor die further comprises a second contact pad at a second side of the semiconductor die, the second contact pad operably connected to a second conductive layer of the power substrate; and
the top-side cooled semiconductor package further comprises:
a third contact within the housing at the bottom side of the housing; and
a second electrical connector operably connecting the third contact to the second conductive layer of the power substrate.

24-26. (canceled)

27. The system of claim 16, wherein:
the at least one side of the housing is the top side; and
the creepage extension structure provides a creepage distance between a pin or a lead and the first contact that is in a range from five millimeters (mm) to twenty mm.

28. (canceled)

29. The system of claim 16, further comprising an interface material between the heat sink and the top side of the housing.

30. (canceled)

31. (canceled)

32. A top-side cooled semiconductor package, comprising:
a housing;
a first contact within the housing at a top side of the housing;
a semiconductor die within the housing below the first contact, the semiconductor die comprising a contact pad at a first side of the semiconductor die;
a power substrate within the housing between the first contact and a second side of the semiconductor die, the first contact and the power substrate included in a thermal transfer path of the top-side cooled semiconductor package;
a second contact within the housing at a bottom side of the housing; and
an electrical connector operably connecting the second contact to the contact pad of the semiconductor die.

33. (canceled)

34. The top-side cooled semiconductor package of claim 32, wherein:
the electrical connector is a first electrical connector;
the contact pad is a first contact pad;
the semiconductor die comprises a second contact pad at the second side of the semiconductor die;
the second conductive layer is operably connected to the second contact pad; and
the top-side cooled semiconductor package further comprises:
a third contact within the housing at the bottom side of the housing; and
a second electrical connector operably connecting the third contact to a conductive layer such that the third contact is operably connected to the second contact pad of the semiconductor die.

35. The top-side cooled semiconductor package of claim 32, further comprising a creepage extension structure that extends into at least one side of the housing, the creepage extension structure comprising one or more trenches.

36-38. (canceled)

39. A top-side cooled semiconductor package, comprising:
a housing;
a first contact within the housing at a top side of the housing, the first contact included in a thermal transfer path of the top-side cooled semiconductor package;
a semiconductor die within the housing below the first contact, the semiconductor die comprising a first contact pad at a first side (top) of the semiconductor die that is operably connected to the first contact and a second contact pad at a second side (bottom) of the semiconductor die;
a second contact within the housing at a bottom side of the housing; and
an electrical connector operably connecting the second contact to the second contact pad of the semiconductor die.

40. The top-side cooled semiconductor package of claim 39, further comprising a creepage extension structure that extends into at least one side of the housing, the creepage extension structure comprising one or more trenches.

41. (canceled)

42. (canceled)

43. The top-side cooled semiconductor package of claim 39, further comprising a second electrical connector operably connected to the first contact.

44-48. (canceled)
